(19) United States
(12) Patent Application Publication
(10) Pub. No.: US 2025/0314725 A1
(43) Pub. Date: Oct. 9, 2025

(54) AUTONOMOUS CURRENT CHARGING OF A SUPER-CONDUCTIVE, DRY-COOLED MR MAGNET COIL SYSTEM

(71) Applicant: Bruker BioSpin GmbH & Co. KG, Ettlingen (DE)

(72) Inventors: Gerald NEUBERTH, Bruchsal (DE); Marco STROBEL, Karlsruhe (DE)

(21) Appl. No.: 18/863,493

(22) PCT Filed: May 3, 2023
(86) PCT No.: PCT/EP2023/061698

§ 371 Date: Nov. 6, 2024

(30) Foreign Application Priority Data
May 6, 2022 (DE) 10 2022 204 476.2

(51) Int. Cl. G01R 33/38; G01R 33/3815

(52) U.S. Cl. CPC G01R 33/3804; G01R 33/3815

(57) ABSTRACT

An operating method for a magnetic resonance (=“MR”) apparatus (10) with a cryogen-free super-conductive MR magnet coil system (12) is characterized by the following steps for autonomous electrical charging of the super-conductive MR magnet coil system:
(a1) initiating a cooling operation of the coil system;
(a2) initiating an automatic current charging program;
(b1) measuring the actual temperature T_{coil} on the coil system and comparing T_{coil} with a predefinable first temperature setpoint value T1ᵣₐₘₚ as of which the coil system is super-conductive and should be charged;
(b2) if T_{coil}≤T1ᵣₐₘₚ: supplying a charging current to the coil system and charging the coil system with electric current;
(c) measuring the electric current I_{coil} currently flowing in the coil system and comparing I_{coil} with a predefinable first current setpoint value I1_{target} at which the coil system generates a desired magnetic field strength;
(d) repeating steps (b1), (b2) and (c) until I_{coil}=|I_{target},
(e) deactivating the current supply to the coil system and stopping the automatic current charging program.

The magnet coil system can thus be autonomously charged with electric current.

The invention relates to a method for operating a magnetic resonance (=“MR”) apparatus with a super-conductive MR magnet coil system arranged in a vacuum container, which is dry (=“cryogen-free”) in MR measurement mode, and with a cryostat for cooling the MR magnet coil system, which comprises a neck tube which leads through an outer casing of the vacuum container to the MR magnet coil system, wherein a cooling arm of a cold head is arranged at least partially in the neck tube, and wherein the super-conductive MR magnet coil system is cooled to a super-conductive temperature and then supplied with an electrical charging current.

Such a method and the associated MR apparatus are known from DE 10 2016 218 000 B3 (=reference [1]).

### BACKGROUND OF THE INVENTION

The present invention relates generally to the field of current charging of super-conductive magnet arrangements which should/must be kept at very low (=cryogenic) temperatures during operation. Such super-conductive magnet arrangements are used, for instance, in the field of magnetic resonance, for example in MRI (=Magnetic Resonance Imaging) tomographs or NMR (=Nuclear Magnetic Resonance) spectrometers.

Nuclear magnetic resonance is a powerful method of instrumental analysis that can be used, in particular, to determine the chemical composition of samples. High-frequency pulses are radiated into the sample, which is located in a strong static magnetic field, and the electromagnetic response of the sample is measured. The strong and in NMR particularly homogeneous static magnetic field is in many cases generated by super-conductive magnet systems, which must be cooled to very low cryogenic temperatures close to absolute zero in measurement mode, usually with the aid of liquid helium as a cryogenic fluid.

Such super-conductive magnet systems are often also equipped with active cooling. The systems then usually no longer have a fluid tank in which the magnets are directly surrounded by cryogenic fluid. Rather, the coils of the magnet systems are arranged in a vacuum container and are therefore “dry,” i.e. cryogen-free, during MR measurement mode. As a rule, the radiation shields surrounding the vacuum container, but sometimes also the magnet systems, are cooled directly by an active cooler, e.g. a pulse tube cooler or a Gifford-MacMahon cooler.

These dry systems are generally more susceptible to malfunctions in the cooling system, for example if the cold head fails, because in contrast to bath-cooled magnet systems, there is no temperature buffer in the form of a cryogen, usually liquid, immediately surrounding the magnet system, which can evaporate if the cooling system fails and thus maintains the cryogenic temperature over a longer period of time. However, these bath-cooled systems require more personnel and higher costs during commissioning because large quantities (up to several thousand liters) of liquid helium and nitrogen are used for cooling and filling and must be refilled in the event of a quench. Accordingly, bath-cooled systems can never be operated autonomously.

The use of active cooling systems reduces in particular the consumption of expensive liquid helium, increases the availability of the NMR apparatus and can also contribute to reducing the overall size. The active cooling system can be single-stage or multi-stage. In multi-stage systems, a warmer cold stage usually cools the thermal radiation shield and a colder cold stage cools the object to be cooled.

### SPECIAL PRIOR ART

U.S. Pat. No. 8,729,894 B2 (=reference [2]) discloses a magnet system for MRI comprising a container with liquid cryogen therein and a super-conductive magnet within the container, wherein the container is configured to be removably connected to a vacuum pump which in turn is configured to pump cryogen from the container to reduce a pressure level within the container to a pumped-down pressure level during start-up of the super-conductive magnet and to increase the pressure level from the pumped-down pressure level to a normal operating pressure level to an increased pressure level during normal magnet operation. Reference [2] further describes a method for charging the magnet, wherein the container with the magnet can be evacuated during ramping. A cold head is arranged in a neck tube without affecting the vacuum in the container. However, the cryostat contains liquid helium. With regard to the present invention, reference [2] represents more distant prior art, since it is a “wet-cooled” coil system, in which self-sufficient operation is not possible.

US 2005/0111159 A1 (=reference [3]) describes an MRI device with a super-conductive magnet, as in reference [2] also helium bath cooled, comprising technology for automatically applying current to the magnet, automatically controlling the ramp-up based on a predefined value of a target parameter (magnetic field strength, current strength or magnet temperature). A so-called “autoramp controller” controls the charging by observing the measured parameters, especially the temperature. In this context, reference [3] discloses a method for automatic commissioning of the super-conductive magnet. The operating values of the limiting parameters should be measured and compared with the setpoint values of the limiting parameters in order to control the current supply. During start-up, the start-up rate in amperes per minute can be controlled based on the magnet current and magnet temperature. The autoramp controller can add current gradually until a certain magnet current is reached. At the same time, the magnet temperature should be prevented from exceeding a predetermined value. However, in reference [3] it is not described how this can be achieved. In particular, reference [3] does not disclose a specific charging algorithm, as is required for charging the very sensitive superconductors, which are not stored in a cooling bath, and which ensures the removal of the hysteresis heat generated during charging. It is only described very generally that a kind of control unit monitors the start-up by measuring various parameters (T and I). There is no provision for interrupting charging if the magnet temperature is too high. The autoramp controller divides the charging operation substantially into two phases, a first fast charging phase and a second slower charging phase, in which there is already current on the coil and a quench is therefore more likely.

From DE 10 2014 218 773 B4 (=reference [4]) it is known to fill a hollow volume between the inside of the neck tube and the cooling arm of a cooling head with a gas, such as helium, in a cryostat. In normal operation, the lowest cooling stage of the cooling arm is located close to the object to be cooled; for example, a close thermal coupling to a small amount of liquid helium in the hollow volume is established via a contact between the object to be cooled and the lowest cooling stage. If the cooling system fails, the gas pressure in the hollow volume increases as a result of the heating; any liquid helium in the hollow volume evaporates. The displaceably mounted cooling head is moved away from the object to be cooled by the increased gas pressure in the hollow volume, thereby reducing the thermal coupling between the cooling arm and the object to be cooled. With this cryostat, the heat load can be reduced by a cooling arm in the event of active cooling failure, but the structural effort is comparatively large due to the movable suspension of the cold head. In addition, due to the high gas pressure in the hollow volume, a significant thermal coupling still remains.

DE 10 2015 215 919 B4 (=reference [5]) describes a method and a device for pre-cooling a cryostat with a heat pipe, as shown in reference [4], for example. During a pre-cooling phase, the object to be cooled is pre-cooled to a target temperature of the working range of the cryogenic working medium in which the heat pipe can work efficiently, wherein for pre-cooling an effectively heat-conducting, precisely fitting short-circuit block is inserted through the neck tube into the heat pipe, one free end of which is thermally connected to a powerful cooling device, the other end of which touches the thermal contact surface. In an intermediate phase after the target temperature has been reached, the short-circuit block is removed from the heat pipe and then heat is transferred through the heat pipe in condensation mode during an operating phase. This allows the time required to pre-cool the cryostat to its operating temperature to be significantly reduced, thus significantly shortening the commissioning time.

US 2021/0080527 A1 (=reference [6]) describes a magnetic resonance tomograph with a super-conductive magnet mounted in a helium-free cryostat. The magnet is cooled via heat pipes that are powered by helium and connected to a cold head. The magnet system also comprises an intelligent monitoring system, which ensures real-time monitoring of the operating states, wherein in particular the temperature (with a T-sensor) and the external current supply is monitored. An operation control system may take appropriate measures, including controlling the heat conduction component and controlling the super-conductive current supply to carry out magnet excitation and demagnetization. Autonomous charging is not disclosed in this document.

The reference [1] already cited at the outset describes a cryostat arrangement with a vacuum container and a cooling object which is arranged inside the vacuum container, which has a neck tube which leads to the cooling object, wherein a cooling arm of a cold head, around which a closed cavity is formed, is arranged in the neck tube, which is sealed fluid-tight with respect to the cooling object and is filled with cryogenic fluid during normal operation. The cryogen in the neck tube can be evaporated for cooling under vacuum and, especially in the event of a failure of the cooling function, pumped out in order to thermally decouple the cold head from the vacuum container. Such a cryostat can be used to carry out the generic method with the feature complexes defined at the outset. However, in reference [1] the charging of a magnet coil with electric current is not even mentioned, let alone described in detail.

In this context, however, the disadvantage of all known relevant methods for current charging of a super-conductive MR magnet coil system that is dry during MR measurement mode, i.e. not surrounded by a cryogenic medium, is the fact that until now, technically skilled personnel have always been required.

Completely autonomous operation of the MR apparatus in this operating phase of electrical charging of the magnet coils, which must always be carried out after the system is first installed by the user, but also each time after an interim heating of the super-conductive magnet, for example during a quench, is not yet possible without the involvement of costly, specially trained service technicians.

The conventional procedure in the prior art therefore always and exclusively involves manual charging of the MR magnet coil system by service staff. The charging plan for the magnet is set and prepared manually on the mains supply unit by the service technician. If the sometimes complex charging plan is handled incorrectly, errors can occur.

Charging processes themselves also take a lot of time and can take several days. This also ties up the working time of the technicians required on site, because manual charging has so far only been carried out during the day for safety reasons. Carelessness during charging can lead to errors such as increased coil temperature or HTS coupling temperature. Such errors can cause a quench or even destruction of the HTS current rods.

DE 10 2021 206 392.6 (=reference [0]), which was still secret on the filing date of the present invention and had not been published until then and was filed by the applicant with the German Patent and Trademark Office on Jun. 22, 2021, describes an autonomous method for autonomously cooling cryostat-based NMR devices, in particular for MRI, at the customer's premises down to a temperature at which the magnet can be charged—recharged if necessary. The invention of this automatic cooling method already eliminates the need for service personnel for this purpose. However, a—in detail very complex-charging program for an equally autonomous electrical charging of the MR magnet coil system automatically and also without active assistance of service employees is not even hinted at in reference [0].

### OBJECT OF THE INVENTION

By contrast, the present invention addresses the—when viewed in detail, initially relatively demanding and complex—problem of improving a method of the type described at the outset for operating an MR apparatus with a super-conductive MR magnet coil system which is arranged “dry” in a vacuum container and is cryogen-free in MR measurement mode, and with a cryostat for cooling this system, and also a device for carrying out this method with inexpensive technical means that are easily obtainable or already generally available to the user as standard, so that the super-conductive MR magnet coil system can be charged with electric current in a predominantly autonomous manner and can also be specifically optimized with regard to certain process parameters, and which runs completely automatically after starting (“at the push of a button”), wherein this should be made possible in the simplest way and without exotic or expensive additional components. In particular, the thermal stress caused by the charging operation should be reduced and the safety against quenching of the superconductor should be increased.

### BRIEF DESCRIPTION OF THE INVENTION

This object is achieved by the present invention in a surprisingly simple and effective manner with regard to the operating method for autonomous electrical charging of the super-conductive MR magnet coil system by the following steps:
(a1) initiating a cooling operation of the super-conductive MR magnet coil system;
(a2) initiating an automatic current charging program for the super-conductive MR magnet coil system;
(b1) measuring the actual temperature T_{coil} on the MR magnet coil system and comparing T_{coil} with a predefinable first temperature setpoint value T1ᵣₐₘₚ as of which the MR magnet coil system is super-conductive and should be charged, wherein T1ᵣₐₘₚ is usually smaller than the critical transition temperature Tc at the transition from the normal conducting to the super-conductive state;
(b2) if T_{coil}≤T1ᵣₐₘₚ: supplying a charging current to the MR magnet coil system and charging the MR magnet coil system with electric current;
(c) measuring the electric current I_{coil} currently flowing in the MR magnet coil system and comparing I_{coil} with a predefinable first current setpoint value I1_{target} at which the MR magnet coil system generates a desired magnetic field strength;
(d) repeating steps (b1), (b2) and (c) until I_{coil}=I1_{target},
(e) deactivating the current supply to the MR magnet coil system and stopping the automatic current charging program.

The automated method according to the invention for charging a super-conductive magnet in helium-free cryostats comprises the steps defined above under predefined charging voltages and strict sensory—but automatic—observation by running a precise computer program. This process would be much more variable, imprecise and error-prone if charging were performed by a technician. This increases the operational reliability of the system at all times. The system is monitored via error messages, which can be sent as emails to remotely stationed and not necessarily permanently active monitoring personnel (e.g. “Caution, gas cylinders are running low”, etc.). The positive result is enormous savings in service personnel and less downtime for the equipment.

In addition, relatively complicated charging operations can also be carried out which would be impossible or very laborious to perform manually, such as cooling and charging over several days and even at night. This means that the valuable magnet system and the expensive NMR system generally have to cope with significantly less downtime. Thanks to the fully monitored and automatic charging, the magnet can also be better utilized in terms of its current carrying capacity. This means it can be developed more compactly and is lighter and more cost-effective to manufacture.

A control unit controls the various components using an algorithm, taking into account various measured values and parameters. The control unit also comprises the automatic current charging program, e.g. on an FPGA, which is called up for the charging process.

An important aspect is the “push-button” principle, whereby the magnets can be charged simply by pressing a button.

A further aim of the present invention may even be to provide a completely self-sufficient magnet system which, at the push of a button, automatically and independently cools down to a sufficiently low cryogenic temperature and then generates an NMR magnetic field of the desired field strength by autonomously electrically charging the MR magnet coil system, without the need for technical monitoring and operating personnel to be on site for the entire complex process.

This goal of automatically cooling down and electrically charging a super-conductive magnet coil can now be achieved by combining the feature complexes of the present invention with the procedures disclosed in reference [0].

This results in a novel operating method which, with the help of a simple control unit-almost at the push of a button-independently cools the super-conductive magnet system and, once a suitable cryogenic temperature has been reached, also automatically charges the magnet coils with electric current.

The system can react accordingly to external disturbances, generate error messages if necessary and send them to a monitoring center, which does not necessarily have to be located on site. In this way, the magnet coil system becomes largely self-sufficient and autonomous and can not only be operated automatically without any further intervention by technical personnel, but can even be brought to operating temperature and field by the end customer themselves in a flexible and easy manner.

The result is enormous savings in service, especially with regard to the use of specialist personnel by the operator of the MR equipment, and reduced downtime of the equipment. The entire system becomes more compact, lighter and more cost-effective in every respect.

An MR apparatus for carrying out the method according to the invention described above is equipped with a super-conductive MR magnet coil system arranged in a vacuum container, which is dry, i.e. cryogen-free, in MR measurement mode and with a cryostat for cooling the MR magnet coil system, which comprises a neck tube that leads through an outer casing of the vacuum container to the MR magnet coil system, wherein a cooling arm of a cold head is arranged at least partially in the neck tube, wherein a closed cavity is formed around the cooling arm and is sealed fluid-tight with respect to the MR magnet coil system to be cooled and is at least partially filled with a cryogenic fluid during normal operation of the MR apparatus.

With regard to such an MR apparatus, the even broader problem of the invention of equally autonomous cooling and electrical charging with physical feature complexes is achieved by arranging a vacuum pump and a first shut-off valve outside the vacuum container in a vacuum line leading from the vacuum pump into the vacuum container, by providing a temperature sensor for measuring an actual temperature T_{coil} on the MR magnet coil system and a first pressure sensor for measuring an actual pressure Pᵢₛₜ in the vacuum container, and in that a control unit is configured to detect and compare the actual temperature T_{coil} on the MR magnet coil system with predefined temperature setpoint values, to detect and compare the actual pressure Pᵢₛₜ in the vacuum container with predefined pressure setpoint values and to actuate a first shut-off valve, the vacuum pump, the cold head and the charging mains supply unit.

A cryostat suitable for carrying out the charging method according to the invention described above in conjunction with the cooling method disclosed in reference [0] contributes to solving the expanded inventive problem by providing a fluid line which opens at one end into a cavity surrounding the cooling arm of the cold head and at the other end into a pressure vessel filled with a cryogenic fluid outside the neck tube, and by providing a second pressure sensor for measuring the actual pressure P_{HR} in the cavity.

Lastly, a device for carrying out such a novel method requires an electronic control unit which is configured to detect and compare an actual temperature T_{coil} on the MR magnet coil system with predefined temperature setpoint values, and to detect and compare an actual pressure Pᵢₛₜ in the vacuum container with predefined pressure setpoint values, and which controls the various components by means of an algorithm taking into account various measured values and parameters. The control unit is essential for the functionality of the autonomous cooling, because it requires continuous detection of the temperature and pressure values and a sensible actuation of the vacuum pump and cooling depending on the available measured values using the algorithm set up for this purpose.

The control unit contributes to the solution of the problem addressed by the invention by having a measuring unit to which a temperature sensor for measuring the actual temperature T_{coil} on the MR magnet coil system and a pressure sensor for measuring the actual pressure Pᵢₛₜ in the vacuum container are connected. Preferably, the measuring unit also comprises a temperature sensor for measuring the actual temperature T_{shield} on the radiation shield of the cryostat. In addition, the control unit comprises an actuating unit for opening and closing the first shut-off valve, for activating and deactivating the vacuum pump and for activating and deactivating the cold head and contains a processor unit which is arranged as an interface between the measuring unit and the actuating unit for comparing the detected sensor parameters with the setpoint parameters and for processing the data for actuating the cold head, vacuum pump, shut-off valve and charging mains supply unit.

### Special Advantages of the Autonomous Cooling and Charging Method According to the Invention

1. Automated cooling and charging procedure during initial commissioning of an MR apparatus with a super-conductive magnet coil system
2. Automated cooling and charging procedure after overheating of the magnet coil system following a failure of the cooling unit or due to a quench (=“Auto Cooling”)
3. Continuous temperature and pressure measurements allow
a) automated checking of the actual temperature T_{coil} on the MR magnet coil system and T_{shield} on the radiation shield;
b) automated checking of the actual pressure Pᵢₛₜ in the vacuum container.

### VARIANTS, PREFERRED EMBODIMENTS AND DEVELOPMENTS OF THE INVENTION

Of very particular advantage is a preferred variant of the method according to the invention in which the following intermediate steps are carried out between step (d) and step (e):
(d1) as soon as I_{coil}=I1_{target}: stopping the cooling operation of the super-conductive MR magnet coil system (this causes the magnet coil system to heat up slowly);
(d2) measuring the actual temperature T_{coil} on the MR magnet coil system and comparing T_{coil} with a predefinable second temperature setpoint value T2ₜₒᵥ<T1c, in which the super-conductive current carrying capacity of the MR magnet coil system is reduced to a predefinable lower value without the superconductivity in the magnet coil system collapsing completely;
(d3) as soon as T_{coil}=T2ₜₒᵥ: restarting the cooling operation of the super-conductive MR magnet coil system.

In this state, the compressor is deactivated and waits until the coil temperature T_{coil} has reached the set temperature limits of T2ₜₒᵥ, i.e. the temperature for thermal overshoot. Depending on the magnet system, this can take up to an hour. As soon as T2ₜₒᵥ is reached, the compressor is activated again and a fixed time, e.g. of about 20 s, is waited to give the compressor time to start. Afterwards, the system switches to an operating state in which the cooling system is activated so that any evaporated helium from the neck tube can be re-liquefied. This also happens if the sensor malfunctions. If the magnet quenches in this state, the temperature T_{coil} increases above a critical value and the charging process must be re-initiated by bringing the temperature of the coil in the cryostat back to T_{coil}≤T1ᵣₐₘₚ.

Through thermal overshoot, the current distribution in the super-conductive filaments is evenly distributed and optimized. This means that the drift specification is reached in a much faster time. MR-specific measurements can thus be started immediately after the thermal overshoot. For conventional magnet systems without thermal overshoot, this can take days to weeks.

The thermal overshoot is preferably part of the automatic charging process and shortens the time required to reach the “drift spec,” i.e. the currents in the super-conductive coil are stabilized to such an extent that the magnetic field no longer changes or changes only slightly. Thus, thermal overshoot ultimately occurs after each charging operation. This serves to force a faster, more even current distribution in the super-conductive filaments by increasing the temperature, so that the magnet reaches its drift spec more quickly (no more recouplings in the filaments).

In conventional bath-cooled magnet systems, overshoot is achieved by slightly overcharging above the setpoint current and then returning to the setpoint current. Surprisingly, the purely thermal overshoot, without changing the current in the coil, has the same effect, namely reaching the drift specs in a timely manner.

Also surprisingly, this time is reduced so drastically that a 7 T magnet is within spec after just one day of thermal overshoot subsiding. Without thermal overshoot, it takes about four days.

With a 9 T magnet it takes a little longer due to the high filament wires and the thermal overshoot is also longer because an elevated temperature range is reached more often and therefore is maintained for longer. The magnet should be in spec after about 2-3 days after the thermal overshoot has subsided. Without thermal overshoot, it would take up to a week or more.

A thermal overshoot in bath-cooled magnets takes an extremely long time because the entire amount of helium has to be warmed up. It is only possible within a limited temperature range.

Variants of the method according to the invention in which steps (d1) to (d3) are repeated several times after the criterion T_{coil}=T2ₜₒᵥ has been reached may also be advantageous. Repeating this several times speeds up the process described above. This also shortens the time until the drift specs are reached. With each thermal overshoot, this decay behavior can be further shortened and, depending on the magnet system, the typical drift values can be reached within a few hours.

In other important variants of the method according to the invention, if T_{coil}>T1ᵣₐₘₚ in step (b2) the charging of the MR magnet coil system 12 with electric current is interrupted and the cooling operation is continued until T_{coil}≤T1ᵣₐₘₚ; then step (b1) is resumed.

The thermal load of the charging operation is reduced by “parking”. This increases the temperature margin compared to T_{c}.

Stopping/interrupting the charging process is normally a transient state and serves to protect against quenching of the superconductor, because the charging operation generates heat that may not be able to be dissipated quickly enough.

When the interruption occurs, the target current is first set to the currently measured current and the voltage to 0V; the main heater and the screening heater are also deactivated so that the magnet is short-circuited. Then the current is noted and the main current is set to 0 A and thus drained from the power cables. As soon as the current is at 0 A, only the cooling remains active.

Particularly preferred is also a class of embodiments of the method according to the invention which are characterized in that a closed cavity is formed around the cooling arm and is sealed fluid-tight with respect to the MR magnet coil system to be cooled and is at least partially filled with liquid helium during normal operation of the MR apparatus, in that the neck tube is connected via a first valve V1 to a helium gas supply, through which helium gas can be introduced on the one hand in order to be liquefied on the cooling arm, and on the other hand in that the helium in the neck tube is pumped out during steps (c) and (d), with the following steps
(c0′) measuring the electric current I_{coil} currently flowing in the MR magnet coil system and comparing I_{coil} with a predefinable second current setpoint value I2ₚᵤₘₚ<I1_{target} as of which the helium in the neck tube is to be pumped out; and
(c0″) as soon as I_{coil}≥I2ₚᵤₘₚ: activating a vacuum pump arranged outside the vacuum container, opening the first shut-off valve in a pumping line leading from the vacuum pump into the neck tube in order to pump helium gas out of the neck tube using the vacuum pump.

By pumping the helium out of the neck tube, even lower temperatures can be reached in the cryostat. On the one hand, this protects the superconductors from heating up during charging and it speeds up the charging process itself because there are fewer interruptions.

This generates additional cooling power, which makes it possible to reach lower temperatures than would be possible with the cold head alone. This means that in the particularly critical range, shortly before reaching the target field, the temperature margin compared to T_{c} is again significantly enlarged. This method allows particularly critical field strengths, designed close to T_{c}, to be reliably reached. This allows smaller, more compact magnet systems to be built.

Developments of these method variants in which the supply line to the neck tube is connected to the vacuum pump via a further valve V3, and in which, in a step (f), helium is fed into the neck tube and liquefied, are advantageous.

Since the volume of helium that can be pumped out is limited to a small amount (e.g. 1.5 l) of liquid helium, pumping is only possible for a certain time, after which helium must be liquefied again. As soon as the pumping time defined in the charging script is exceeded, helium must be liquefied.

This makes it possible to refill and liquefy any helium that may have been pumped out during charging. This ensures that if the cooling unit fails, the full helium volume is always available for evaporation. This can extend the time until a quench after a cooler failure to several hours.

The above-mentioned method variants can alternatively or additionally be further developed by pumping out the liquid helium in the neck tube with the vacuum pump in a step (c0′″) between steps (c) and (d), possibly before steps (d1) to (d3), if necessary, for example in the event of failure of the cold head, in order to cool the MR magnet coil system.

This makes it possible to build magnet systems that have a design temperature below the evaporation temperature of helium (4.2K). This allows smaller, more compact magnet systems to be built.

This method step serves to protect against quenching of the superconductor if the cold head actually fails, because then the time until heating to the transition temperature is extended.

Also preferred are embodiments of the method according to the invention in which, in step (b1), additionally the actual temperature T_{istshield} on a radiation shield is measured and compared with a predefinable temperature setpoint value T_{shield} and, if T_{istshield}≤T shield, the charging current is supplied according to step (b2).

This prevents the HTS current rods from reaching their critical temperature and burning out during the charging operation of the magnet.

The current supply to the super-conductive magnet during the charging operation takes place through current rods, which contain good electrical conductors. In the case of cryogen-free magnets, high-temperature superconductors (=HTS) are used because they cause less heat input into the cryostat compared to, for example, copper. The HTS current rods are usually thermally connected to the radiation shield, which at a temperature T_{shield} should be below the transition temperature of the HTS conductor so that the HTS conductor does not quench and thus is not destroyed during the charging process. Therefore, monitoring the radiation shield temperature is necessary.

These method variants can also be further developed in that, if T_{istshield}>T_{shield}, the charging of the MR magnet coil system with electric current is interrupted in step (b2) and the cooling operation is continued until T_{istshield}≤T_{shield}, after which the method is resumed in step (b1).

This prevents the HTS current rods from reaching their critical temperature and burning out during the charging operation of the magnet. If the radiation shield temperature reaches a critical range for the HTS conductor, charging should be interrupted to avoid HTS quench. By “parking” the charging operation, the HTS current rods cool down.

As already mentioned above in conjunction with the autonomous cooling operation, a special electronic control unit is required to automatically carry out the process sequence. This also applies to the present autonomous charging method according to the invention. A very particularly preferred class of embodiments of the method according to the invention is therefore characterized in that the autonomous electrical charging operation of the super-conductive MR magnet coil system is automatically regulated by means of an electronic control unit, wherein the control unit is configured to detect and compare the actual temperature T_{coil} on the MR magnet coil system or up to T_{istshield} on the radiation shield with predefined temperature setpoint values, to detect and compare the electric current I_{coil} currently flowing in the MR magnet coil system with predefined current setpoint values and, if necessary, to actuate valves, a charging mains supply unit, a vacuum pump and functional units of the cold head.

The electronic control unit plays a central role in connection with the charging operation because it comprises the automatic current charging program, which comprises a charging script optimized for each magnet class, ensuring standardized and safe charging of the magnet. This means that highly complex, self-monitored charging operations with breaks and variable limit values can be carried out safely and reliably in a temperature-optimized manner, and if necessary over very long periods of time.

Advantageous here are developments of this class of method variants in which the electronic control unit regulates the autonomous electrical charging operation of the super-conductive MR magnet coil system completely automatically by means of an algorithm taking into account various measured values and parameters, such as pressure, temperature, charging voltage, charging current, on its own in the absence of operating or monitoring personnel, even overnight, in particular over several days, without any time interruption.

This also allows highly complex, self-monitored charging operations with breaks and variable limit values to be carried out safely and reliably in a temperature-optimized manner, and if necessary over very long periods of time.

These developments can be further improved by the electronic control unit independently detecting critical changes in state and errors in the super-conductive MR magnet coil system and the cryostat for cooling the MR magnet coil system, in particular the temperatures, currents and pressure values in the vacuum container, during the autonomous electrical charging operation of the super-conductive MR magnet coil system and reacting to this either by using a predefinable alternative algorithm for further regulation of the autonomous electrical charging operation and/or by sending messages or error messages, for example email messages, to operating or monitoring personnel.

In this way, early intervention is possible if a problem or even a magnet quench is imminent. For example, emails can be sent to facility management in the event of a cooling water failure or, for instance, to the magnet service in the event of an increased shield temperature. This significantly reduces the possible downtime and prevents MR measurement interruptions

Alternatively or additionally, the described class of method variants can also be developed in that the electronic control unit has access to one or more different algorithms for the autonomous electrical discharging or partial discharging of the super-conductive MR magnet coil system from an electrically charged state, and in that the discharging operation is regulated completely automatically by the electronic control unit with presettable boundary conditions.

This also allows highly complex, self-monitored charging operations with breaks and variable limit values to be carried out safely and reliably without service technicians in a temperature-optimized manner, and if necessary over very long periods of time. The operating and maintenance costs of a magnet system are thus significantly reduced.

Preferred embodiments of the method according to the invention are characterized in that the predefinable temperature setpoint values T1ᵣₐₘₚ and T2ₜₒᵥ and the predefinable current setpoint values I1_{target} and I2ₚᵤₘₚ can be selected from the following-exemplary and in principle manageable-value ranges:
2K<T1ᵣₐₘₚ≤5K, preferably about 4.2K;
2K≤T2ₜₒᵥ<6K, preferably about 4.2K;
50 A<I1_{target}≤500 A, preferably about 250 A
30 A≤I2ₚᵤₘₚ<400 A, preferably about 350 A
30K≤T_{shield}<77K, preferably about 65K.

Further predefinable temperature setpoint values T1ₛₒₗₗ, T2ₛₒₗₗ and T3ₛₒₗₗ and a predefinable pressure setpoint value P1ₛₒₗₗ are selected from the following value ranges:
5K≤T1ₛₒₗₗ≤20K, preferably about 8K;
3K≤T2ₛₒₗₗ≤5K, preferably about 4.2K;
250K≤T3ₛₒₗₗ≤300K, preferably about 280K
10⁻⁴ mbar≤P1ₛₒₗₗ≤10⁻¹ mbar, preferably about 10⁻³ mbar.

These values are used when the MR coil system contains LTS conductors (low-temperature superconductors), which typically operate at the temperature of liquid helium, i.e. less than 4.2K. The cryogenic fluid in the neck tube is therefore helium.
T1ₛₒₗₗ corresponds to the temperature from which the vacuum in the vacuum container must be restored.
T2ₛₒₗₗ corresponds to the operating temperature of the MR magnet coil system when using LTS conductors.
T3ₛₒₗₗ corresponds to the temperature of a fully warmed up magnet coil system.
P1ₛₒₗₗ is the minimum vacuum in the vacuum chamber from which it can be assumed that only a few residual gases are present and therefore cooling can begin.

The magnetic resonance (“MR”) apparatus already described above for carrying out the method according to the invention also falls within the scope of the present invention. In advantageous embodiments, this can be designed such that the vacuum pump is constructed in at least two stages and has a turbomolecular pump and a backing pump for this purpose, preferably a diaphragm pump. Both pumps are preferably connected in series. As a rule, only these two-stage pumps achieve a sufficient high vacuum.

Furthermore, the cryostat—also described above and required for the MR apparatus according to the invention—for cooling the MR magnet coil system can be developed in that the end of the fluid line connected to the cavity opens via a second shut-off valve into a region of the vacuum line between the first shut-off valve and the turbomolecular pump, and in that the end of the fluid line connected to the pressure vessel opens via a third shut-off valve into a region of the vacuum line between the turbomolecular pump and its backing pump. The separate valves mean that the helium supply is arranged separately from the vacuum pumps so that the helium supply is not pumped dry when pumping on the neck tube.

The scope of the present invention also includes a control unit for carrying out the method according to the invention, as also already described above.

Particularly preferred is a class of embodiments of the control unit according to the invention which are characterized in that the second pressure sensor for measuring the actual pressure P_{HR} in the cavity surrounding the cooling arm of the cold head is connected to the measuring unit, and in that the actuating unit is configured to open and close the second and third shut-off valves.

When the magnet coil system is still warm, the measurement of P_{HR} is used to monitor the pressure during the initial flushing of the neck tube with He. The neck tube is alternately emptied via V2 and filled with helium via V1 with the vacuum pump, preferably with the diaphragm pump when using a two-stage pump, so that as few foreign gases as possible are present in the neck tube before cooling.

The measurement of P_{HR} also serves to monitor whether there is sufficient helium in the pressure vessel after cooling down has been completed in order to monitor the filling of the neck tube with helium. It is also used to check the pressure gauge setting on the helium pressure vessel during operation to ensure that no overpressure or underpressure occurs on the supply line.

In practice, developments of these embodiments have proven successful in which there is a connection from the neck tube to the vacuum pump, wherein the control unit regulates the control of V2 to the vacuum pump. The vacuum pump is used, on the one hand, to completely free the neck tube of foreign gases if the cryostat heats up too much before cooling begins. This prevents the freezing-up of foreign substances, which would impair the functionality of the cold head. On the other hand, the vacuum pump can usefully be used in a cold state to delay the heating of the cryostat by pumping out the existing helium in the event of a cold head failure. The control unit regulates the actuation of V2 and vacuum pump depending on the measured parameters.

Alternatively or additionally, other developments are characterized in that a connection from a helium gas supply to the neck tube is provided, and in that the control unit regulates the control of the He supply via the first valve V1. In this way, after power or water outages, helium can be liquefied in a controlled manner to refill the small reservoir in the neck tube. This ensures that there is always enough liquid helium in the neck tube to survive for several hours without quenching in the event of a cooler failure.

Applications of the method variants and devices according to the invention are particularly preferred in the field of magnetic resonance, in particular in NMR spectroscopy and in MRI apparatuses.

Further advantages of the invention can be found in the description and the drawings. Likewise, according to the invention, the aforementioned features and those which are to be explained below can each be used individually or together in any desired combinations. The embodiments shown and described are not to be understood as an exhaustive list, but, rather, have an exemplary character for the description of the invention.

### DETAILED DESCRIPTION OF THE INVENTION AND DRAWINGS

The invention is shown in the drawings and is explained in more detail using exemplary embodiments.

In the drawings:

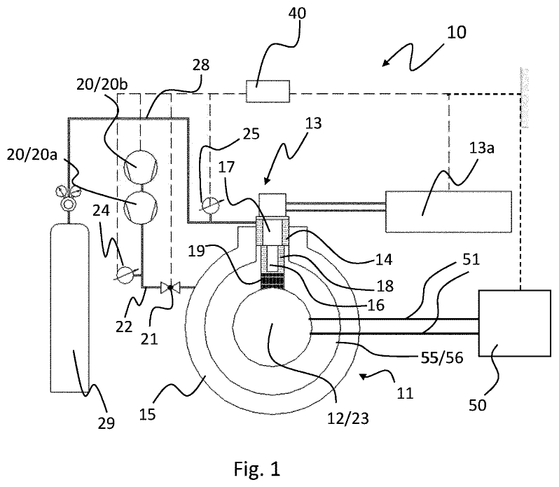

FIG. 1 is a schematic vertical sectional view of an embodiment of the magnetic resonance apparatus in the 1-valve version for carrying out the auto-charging method according to the invention;

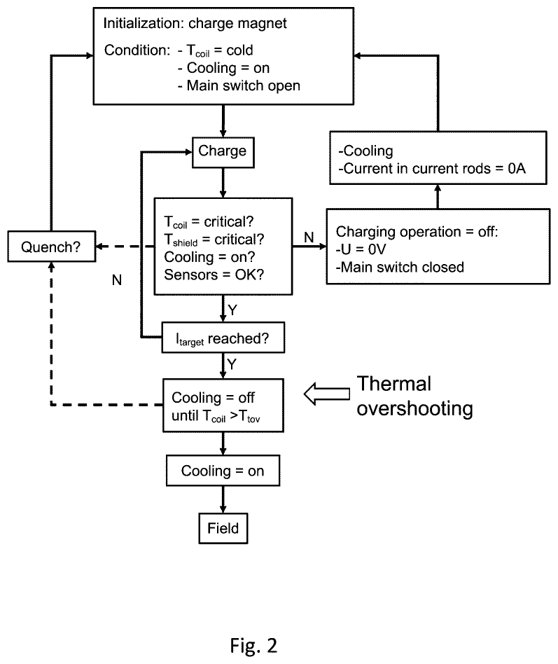

FIG. 2 is a flow diagram of the basic method sequence of the auto-charging method according to the invention with thermal overshooting in the form of an algorithm as it is to run in a corresponding program in the control unit, preferably for embodiments in the 1-valve version as in FIG. 1;

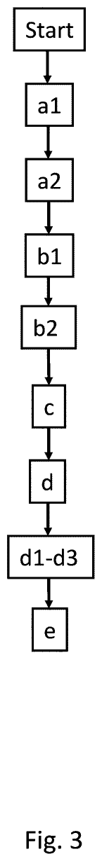

FIG. 3 is a schematic flow diagram with the method steps according to the claims in embodiments preferably in the 1-valve version as in FIG. 1;

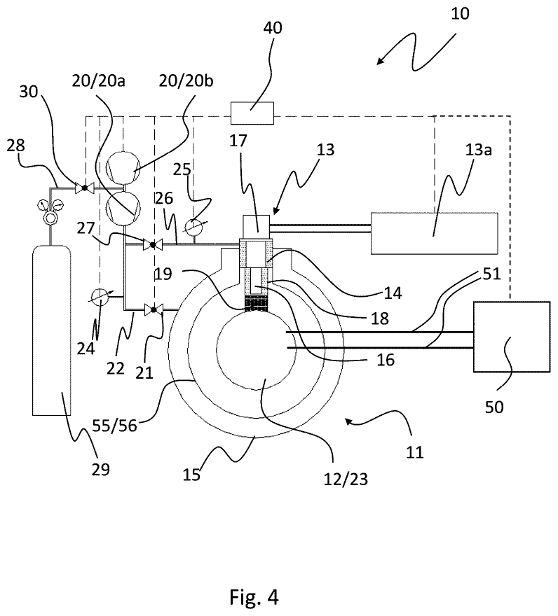

FIG. 4 is a schematic vertical sectional view of an embodiment of the magnetic resonance apparatus in the 3-valve version for carrying out the auto-charging method according to the invention;

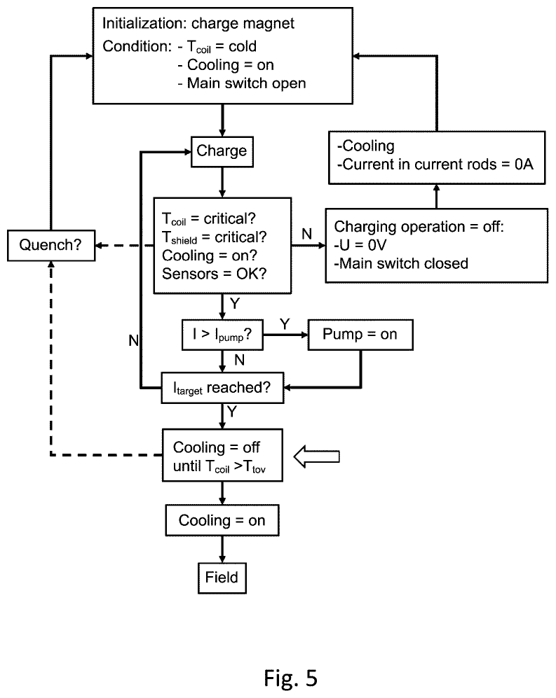

FIG. 5 is a flow diagram of the basic method sequence of the auto-charging method according to the invention with thermal overshooting in the form of an algorithm as it is to run in a corresponding program in the control unit, for embodiments in the 3-valve version as in FIG. 4;

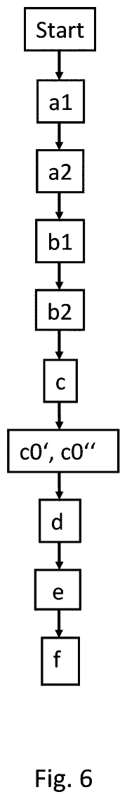

FIG. 6 is a schematic flow diagram with the method steps according to the claims in the sub-variant with helium liquefaction in embodiments in the 3-valve version as in FIG. 4;

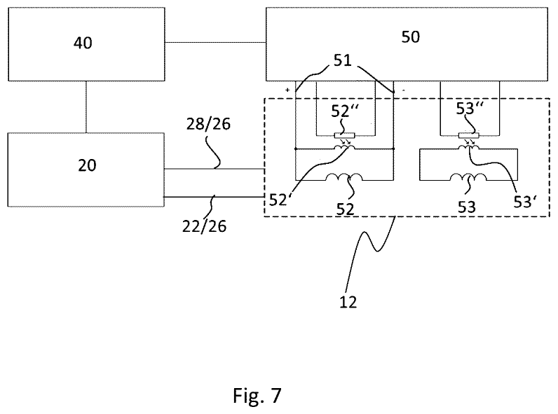

FIG. 7 is a setup scheme of a device for autonomous electrical charging according to the invention of the super-conductive MR magnet coil system of an MR apparatus, with a schematic coil system, charging mains supply unit, pump unit and control unit for controlling the charging operation;

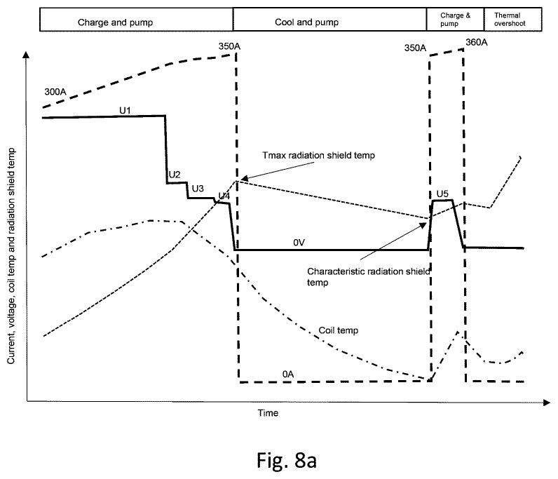

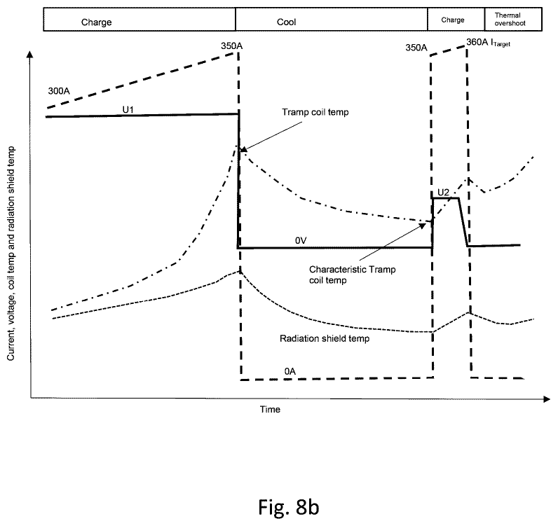

FIG. 8a is a schematic time diagram for the method variant “Charging interruption (=parking) when a maximum predefined radiation shield temperature is reached”;

FIG. 8b is a schematic time diagram for the method variant “Charging interruption when a maximum predefined coil temperature is reached”;

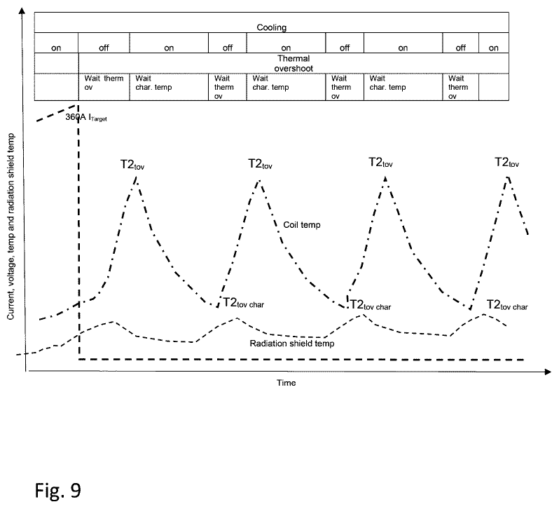

FIG. 9 is a schematic time diagram for a method variant of the auto-charging operation according to the invention with multiple instances of “thermal overshooting”;

and

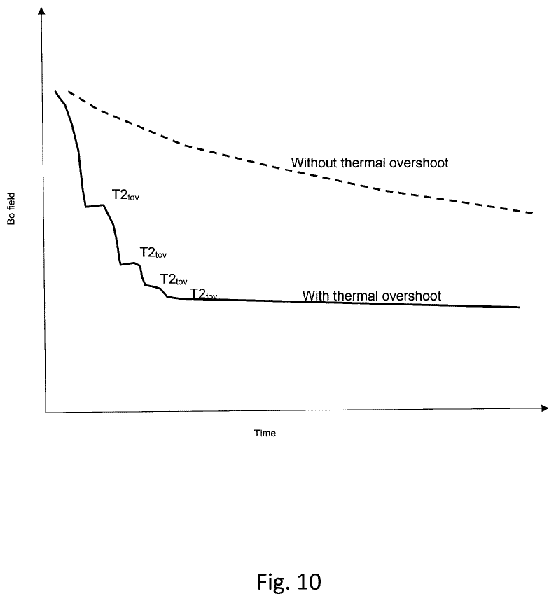

FIG. 10 is a schematic time diagram of the drift behavior after charging with and without “thermal overshooting”.

The present invention substantially concerns a specially modified method for operating a magnetic resonance apparatus 10 (=“MR apparatus”), in particular with the autonomous cooling of a super-conductive magnet arrangement.

FIG. 1 shows schematically a particularly simple embodiment of the magnetic resonance apparatus 10 with only one valve for carrying out the auto-cooling method according to the invention.

The MR apparatus 10 comprises a vacuum container 11 with a super-conductive MR magnet coil system 12. In MR measurement mode, this MR magnet coil system 12 is dry, i.e. cryogen-free. Cooling is provided by a cryostat 13, which is connected to a compressor 13a. The cryostat 13 contains a neck tube 14, which leads through an outer casing 15 of the vacuum container 11 to the MR magnet coil system 12. In the neck tube 14 of the cryostat 13 there is arranged a cooling arm 16 of a cold head 17. A cavity 18 is formed around the cooling arm 16. The cavity 18 is sealed fluid-tight with respect to the MR magnet coil system 12 to be cooled. In the operating state shown here, the cavity 18 is partially filled with a cryogenic fluid 19 (e.g. liquid helium) and gaseous helium.

Outside the vacuum container 11 there is arranged a vacuum pump 20 which is formed here as a 2-stage vacuum pump 20. The vacuum pump 20 comprises a turbomolecular pump 20a with a backing pump 20b (e.g. a diaphragm pump). The vacuum pump 20 is connected to the vacuum container 11 via a vacuum line 22 with a first shut-off valve 21 (shut-off valve V3).

On the MR magnet coil system 12 there is provided a temperature sensor 23 to measure an actual temperature T_{coil} on the MR magnet coil system 12. A first pressure sensor 24, which is connected to the vacuum container 11 via the vacuum line 22, measures an actual pressure Pᵢₛₜ in the vacuum container 11. A control unit 40 detects and compares the actual temperature T_{coil} on the MR magnet coil system 12 with predefined temperature setpoint values. Furthermore, the control unit 40 detects and compares the actual pressure Pᵢₛₜ in the vacuum container 11 with predefined pressure setpoint values. The control unit 40 is further configured such that it can actuate the first shut-off valve 21, the vacuum pump 20 and the compressor 13a of the cold head 17.

For the method according to the invention for autonomous electrical charging of the super-conductive MR magnet coil system 12, an automatic current charging program is initiated after the initiation of a suitable cooling operation. The charging current is supplied here to the MR magnet coil system 12 from a charging mains supply unit 50 via current rods 51.

The figure also shows a radiation shield 55, which may be equipped with a temperature sensor 56 (not specifically shown here). The HTS current rods 51 are thermally connected to the radiation shield 55, ensuring that these HTS parts are cooled below the transition temperature.

The control unit 40 includes a measuring unit, an actuating unit and a processor unit. The temperature sensors 23 and 56 are connected to the measuring unit and are used to measure the actual temperature T_{coil} and T_{istshield} on the MR magnet coil system 12 and at the radiation shield 55, respectively. Furthermore, the pressure sensor 24 is connected to the measuring unit and is used to measure the actual pressure Pᵢₛₜ in the vacuum container 11. The actuating unit is connected to the first shut-off valve 21, which can open and close the actuating unit. Furthermore, the actuating unit is connected to the vacuum pump 20 and the cold head 17 (or the compressor 13a), which can activate and deactivate the actuating unit. The processor unit is arranged between the measuring unit and the actuating unit. The processor unit compares the detected parameters of the temperature sensor 23 and the pressure sensor 24 with the setpoint parameters. These data are processed by the processor unit and used to actuate the cold head 17, the vacuum pump 20, the shut-off valve 21 and in particular the charging mains supply unit 50.

A second pressure sensor 25, which is connected to a connection 28 which leads from a helium supply 29 into the cavity 18 of the cryostat 13, can be used to measure the actual pressure P_{HR} in the cavity 18. The second pressure sensor 25 is also connected to the measuring unit of the processor unit.

The basic sequence of the charging method according to the invention for embodiments with thermal overshooting and with only one valve is shown in FIG. 2 as a flow diagram.

### EXEMPLARY EMBODIMENT

The sequence of the charging method according to the invention can comprise the following steps in the 1-valve variant:

After the cooling process (a1) of the magnet has been completed and the cooling is still on, the charging process can be initiated by starting the current charging program (a2), which can also be started by a non-expert by simply operating a corresponding switch. The program runs through the method by first (b1) measuring the actual temperature T_{coil} and, if necessary, T_{istshield}. When the temperatures have reached the target value from which the MR magnet coil system 12 and the HTS current rods are super-conductive and can be charged, in step (b2) the charging current is supplied to the MR magnet coil system 12 and the MR magnet coil system 12 is charged with electric current.

During charging, the target current is set step by step according to a charging plan adapted to the magnet. If the measured current is close to the applicable setpoint current, the next level is set. The charging voltage is set according to the charging plan depending on the measured current. At the end, the target current I1_{target} is reached. As soon as I1_{target} is reached, the charging mains supply unit 50 automatically stabilizes the I1_{target} by lowering the charging voltage to 0V (switching from voltage to current regulation).

During charging, the temperatures T_{coil} and T_{istshield} are continuously checked, as is also the functioning of the cooling and the necessary monitoring sensors. As soon as an error message is received in the control unit 40, the charging operation is interrupted and a change to “parking” is initiated. In the “parking” state, the target current is first set to the currently measured current and the voltage to 0V, and the main heater 52″ and the screening heater 53″ are deactivated. The current is drained from the current rods 51 and cooling continues until the setpoint temperatures are reached again, then step (b1) is resumed.

Furthermore, during charging, in a step (c), the electric current I_{coil} currently flowing in the MR magnet coil system 12 is measured and compared with a predefinable first current setpoint value I1_{target} at which the MR magnet coil system 12 generates a desired magnetic field strength. Optionally, in a step (d), steps (b1), (b2) and (c) can be repeated until I_{coil}=I1_{target}. When this value is reached, thermal overshooting occurs in steps (d1) by stopping cooling and (d2) monitoring the temperature. As soon as T_{coil}=T2ₜₒᵥ is reached, the cooling is started again (d3). The magnet is then at spec and the current charging program is terminated in step (e).

FIG. 3 shows a schematic flow diagram of the autonomous charging method with the method steps according to the claims for embodiments with only one valve.

FIG. 4 shows schematically a particularly simple embodiment of a magnetic resonance apparatus 10 (MR apparatus) with three valves for carrying out the auto-cooling method according to the invention.

The MR apparatus 10 comprises the vacuum container 11 with the super-conductive MR magnet coil system 12. In MR measurement mode, this MR magnet coil system 12 is dry, i.e. cryogen-free. Cooling is achieved via a cryostat 13, which is connected to the compressor 13a. The cryostat 13 contains the neck tube 14, which leads through the outer casing 15 of the vacuum container 11 to the MR magnet coil system 12. The cooling arm 16 of the cold head 17 is arranged in the neck tube 14 of the cryostat 13. The cavity 18 is formed around the cooling arm 16. The cavity 18 is sealed fluid-tight with respect to the MR magnet coil system 12 to be cooled. In the operating state shown here, the cavity 18 is partially filled with cryogenic fluid 19 (e.g. liquid helium) and gaseous helium.

Outside the vacuum container 11 there is arranged the vacuum pump 20 which is formed here as a 2-stage vacuum pump 20. The vacuum pump 20 comprises the turbomolecular pump 20a with the backing pump 20b (e.g. a diaphragm pump). The vacuum pump 20 is connected to the vacuum container 11 via the vacuum line 22with the first shut-off valve 21 (shut-off valve V3). Furthermore, the vacuum pump 20 is connected to the neck tube 14 via a connection 26 with a second shut-off valve 27 (shut-off valve V2).

On the MR magnet coil system 12 there is provided the temperature sensor 23 for measuring an actual temperature T_{coil} on the MR magnet coil system 12. The first pressure sensor 24, which is connected to the vacuum container 11 via the vacuum line 22, measures an actual pressure Pᵢₛₜ in the vacuum container 11. The second pressure sensor 25, which is connected to the neck tube 14 via the connection 26, measures an actual pressure P_{HR} in the neck tube. The control unit 40 (not shown here) detects and compares the actual temperature T_{coil} on the MR magnet coil system 12 with predefined temperature setpoint values. Furthermore, the control unit 40 detects and compares the actual pressure Pᵢₛₜ in the vacuum container 11 with predefined pressure setpoint values. The control unit 40 is further configured such that it can actuate the first shut-off valve 21, the vacuum pump 20 and the compressor 13a of the cold head 17.

The control unit 40 includes the measuring unit, the actuating unit and the processor unit. The temperature sensor 23 is connected to the measuring unit and is used to measure the actual temperature T_{coil} on the MR magnet coil system 12. Furthermore, the first pressure sensor 24 is connected to the measuring unit and is used to measure the actual pressure Pᵢₛₜ in the vacuum container 11. Likewise, the second pressure sensor 25 is connected to the measuring unit and is used to measure the actual pressure P_{HR} in the neck tube 14. The actuating unit is connected to the first shut-off valve 21, the second shut-off valve 27 and a third shut-off valve 30 (shut-off valve V1), which can open and close the actuating unit.

The shut-off valve 30 is integrated into the connection 28, which connects the helium supply 29 and the neck tube 14. Furthermore, the actuating unit is connected to the vacuum pump 20 and via the compressor 13a to the cold head 17, which can activate and deactivate the actuating unit. The processor unit is arranged between the measuring unit and the actuating unit. The processor unit compares the detected parameters from the temperature sensor 23, the pressure sensor 24 and the pressure sensor 25 with the setpoint parameters. These data are processed by the processor unit and used to control the cold head 17, the vacuum pump 20, the shut-off valves 21, 27, 30 and the charging mains supply unit 50.

Also in this embodiment, the charging current is supplied to the MR magnet coil system 12 from a charging mains supply unit 50 via current rods 51. In addition, a radiation shield 55 is also shown here, which may be equipped with a temperature sensor (again not specifically shown here).

The basic sequence of the charging method according to the invention for embodiments with three valves is shown in FIG. 5 as a flow diagram.

### Exemplary Embodiment

The sequence of the charging method according to the invention can comprise the following steps in the 3-valve variant:

After the cooling process (a1) of the magnet has been completed and the cooling is on, the charging process can be initiated by starting the current charging program (a2), which can also be started by a non-expert by simply operating a switch. The program runs through the method by first (b1) measuring the actual temperature T_{coil} and, if necessary, T_{istshield}. When the temperatures have reached the target value from which the MR magnet coil system 12 and the HTS current rods are super-conductive and can be charged, in step (b2) the charging current is supplied to the MR magnet coil system 12 and the MR magnet coil system 12 is charged with electric current.

During charging, the target current is set step by step according to a charging plan adapted to the magnet. If the measured current is close to the applicable setpoint current, the next level is set. The charging voltage is set according to the charging plan depending on the measured current. At the end, the target current I1_{target} is reached. As soon as I1_{target} is reached, the charging mains supply unit automatically stabilizes the I1_{target} by lowering the charging voltage to 0V (switching from voltage to current regulation).

During charging, the temperatures T_{coil} and T_{istshield} are continuously checked, as is also the functioning of the cooling and the necessary monitoring sensors. As soon as an error message is received in the control unit 40, the charging operation is interrupted and a change to “parking” is initiated. In the “parking” state, the target current is first set to the currently measured current and the voltage to 0V, and the main heater 52″ and the screening heater 53″ are deactivated. The current is drained from the current rods and cooling continues until the setpoint temperatures are reached again, then step (b1) is resumed.

Furthermore, during charging, in a step (c), the electric current I_{coil} currently flowing in the MR magnet coil system 12 is measured and compared with a predefinable first current setpoint value I1_{target} at which the MR magnet coil system 12 generates a desired magnetic field strength. In order to achieve improved cooling performance during charging, especially when the charging current increases above a setpoint value and leads to the risk of heating up the superconductors, the vacuum pump 20 is activated and the first shut-off valve 27 is opened in intermediate steps (c0′) and (c0″) so that liquid helium is pumped out of the neck tube. Charging can continue during pumping.

Optionally (d), steps (b1), (b2) and (c) may be repeated until I_{coil}=I1_{target}. When this state is reached, thermal overshooting occurs in steps (d1) by stopping cooling and (d2) monitoring the temperature. As soon as T_{coil}=T2ₜₒᵥ is reached, the cooling is started again (d3). The magnet is then at spec and the current charging program is terminated in step (e).

FIG. 6 shows a schematic flow diagram of the autonomous charging method according to the invention with the method steps according to the claims for embodiments with three valves.

FIG. 7 shows the structural scheme of a device for the autonomous electrical charging according to the invention of the super-conductive MR magnet coil system 12 of an MR apparatus 10 with a schematically illustrated coil system comprising a main coil 52 with a main switch 52′ and a main heater 52″ and a shield coil 53 with a shield switch 53′ and a shield heater 53″, with a charging mains supply unit 50, with current rods 51, with a pump unit which has one or more vacuum pumps 20, and with a control unit 40 for controlling the charging operation.

Normally, the magnet charging unit 50 is actuated through an interface via Ethernet. To charge the main coil 52, the main switch 52′ must be opened, which is done by heating a part of the main coil 52 by the main heater 52″. The heated part thereby loses superconductivity and the main switch 52′ is open. Accordingly, the main switch 52′ is closed when the charging process is terminated to short-circuit the super-conductive main coil 52. Even if the charging operation is interrupted, e.g. if a predefined coil temperature or shield temperature is exceeded, the main switch 52′ is closed before the current is drained from the current rods.

The shield coil 53 serves to compensate for external field disturbances. During the charging/discharging operation, the shield coil 53 would be inductively charged until a quench occurred. To prevent this, the shield coil 53 is opened via the shield switch 53′ during charging and discharging, which is done by heating the shield heater 53″.

FIG. 8a schematically shows the time sequence for the method variant “Parking when a maximum predefined radiation shield temperature is reached.”

A typical charging operation with pumping during charging is shown. The thick dashed curve shows the charging current, while the charging voltage is represented by the solid curve. The thin dashed line shows the radiation shield temperature T_{istshield} and the chain dotted line shows the coil temperature T_{coil}.

By pumping during charging, the charging losses are compensated to such an extent that a slight increase in coil temperature can be seen. Charging takes place step by step at different voltages U1, U2, U3 and U4. By reducing the charging voltage, further charging losses are minimized, thus the coil temperature drops further. However, with increasing charging current, the radiation shield temperature T_{istshield} also increases, since the current supply (practically always embodied as an HTS part) is thermally coupled to the radiation shield 55. If the limit value of Tₘₐₓ is exceeded at the radiation shield 55, in this case at a charging current of 350 A, the magnet is parked by the charging algorithm: The super-conductive switches 52′, 53′ close, current is drained from the supply lines. The magnet cools and thus also the radiation shield temperature T_{istshield}. Pumping continues at the neck pipe 14 to accelerate the cooling process. As soon as the characteristic radiation shield temperature is reached, the charging operation is activated again until the current setpoint value I_{Target} is reached. This is followed by the “thermal overshooting”.

FIG. 8b schematically shows a corresponding time diagram for the method variant “Parking when a maximum predefined coil temperature is reached.” A similar curve is shown as in FIG. 8a, only here charging is carried out at a constant charging voltage U1, which leads to a continuous increase in the coil temperature up to T_{coil}=Tᵣₐₘₚ. In this example, the coil temperature Tᵣₐₘₚ is used as the interruption (“parking”) criterion. Here, the cooling operation takes place during the charging interruption without pumping out the helium in the neck tube. This variant is preferably used for smaller magnets (<9 T).

FIG. 9 shows a schematic time diagram for a method variant of the auto-charging method according to the invention with multiple instances of “thermal overshooting”.

After reaching the predefined first current setpoint value 11 target, at which the MR magnet coil system 12 generates a desired magnetic field strength, the thermal overshooting method variant is carried out. In the exemplary embodiment shown, several thermal overshoots—here a total of four—are run through. By deactivating the cooling, the coil temperature T_{coil} is increased in each case to the predefined second temperature setpoint value T2ₜₒᵥ<TC at which the super-conductive current carrying capacity of the MR magnet coil system 12 is reduced to a desired lower value without the superconductivity in the magnet coil system 12 exceeding the critical transition temperature T_{c} at the transition from the normal conducting to the super-conductive state and collapsing completely. This desired maximum temperature T2ₜₒᵥ is close to the critical transition temperature T_{c}, but with a safety margin, usually on the order of about 100 mK.

With each thermal overshoot cycle, the superconductor of the MR magnet coil system 12 is loaded slightly more, which ultimately leads to an optimized current distribution in the super-conductive filaments. Thus, the specified drift of the MR magnet coil system 12 is reached much faster than, for example, in bath-cooled magnet systems or in systems without the use of thermal overshooting.

Alternatively, it would be possible to keep the coil temperature at the maximum temperature T2ₜₒᵥ for a longer period of time instead of running several overshoot cycles. However, this alternative is less practical because the cold heads used are not suitable for maintaining a constant temperature.

FIG. 10 lastly shows the temporal progression of the drift behavior of an MR magnet coil system 12 after charging with and without thermal overshooting:

After charging a super-conductive magnet in persistent mode, a temporal decay behavior of the magnetic field typically begins. This can usually be explained by recouplings in the super-conductive filaments. Only then does the conductor-related and joint-related drift behavior occur with typical values of less than 0.05 ppm/h. However, this “natural” decay behavior can last for several days or weeks, depending on the type of magnet and conductor. With a targeted application of thermal overshoot, this decay behavior can be significantly shortened and, depending on the magnet system, the typical long-term drift values can be reached within a few hours. In the progression shown by way of example in FIG. 10 with thermal overshoot, the multiple, in this example four, overshoot steps are clearly visible.

### LIST OF REFERENCE SIGNS

10 magnetic resonance (“MR”) apparatus
11 vacuum container
12 MR magnet coil system
13 cryostat
13a compressor
14 neck tube
15 outer casing
16 cooling arm
17 cold head
18 cavity
19 cryogenic fluid
20 vacuum pump
20a turbomolecular pump
20b backing pump
21 shut-off valve (V3)
22 vacuum line
23 temperature sensor
24 first pressure sensor
25 second pressure sensor
26 connection line (from the neck tube to the vacuum pump)
27 shut-off valve (V2)
28 connection line (from helium supply to the neck tube)
29 helium supply
30 shut-off valve (V1)
40 control unit
50 charging mains supply unit
51 current rods
52 main coil
52 main switch
52″ main heater
53 shield coil
53′ shield switch
53″ shield heater
55 radiation shield
56 temperature sensor

### LIST OF REFERENCES

Publications considered for the assessment of patentability:
[0] DE 10 2021 206 392.6
[1] DE 10 2016 218 000 B3≈WO 2018/054648 A1≈EP 3 296 669 B1≈CN 107845474 B≈JP 6338755 B≈U.S. Pat. No. 10,101,420 B2
[2] U.S. Pat. No. 8,729,894 B2
[3] US 2005/0111159 A1
[4] DE 10 2014 218 773 B4≈CN 105501679 B≈GB 2532322 B≈U.S. Pat. No. 10,203,067 B2
[5] DE 10 2015 215 919 B4≈GB 2542667 B≈U.S. Pat. No. 10,203,068 B2
[6] US 2021/0080527 A1

1. A method for operating a magnetic resonance (MR) apparatus with a super-conductive MR magnet coil system which is arranged in a vacuum container and is cryogen-free in MR measuring mode, and with a cryostat for cooling the MR magnet coil system, which comprises a neck tube that leads through an outer casing of the vacuum container to the MR magnet coil system, wherein a cooling arm of a cold head is arranged at least partially in the neck tube, and wherein the super-conductive MR magnet coil system is cooled to a super-conductive temperature before being supplied with an electrical charging current, the method comprising:
providing autonomous electrical charging of the super-conductive MR magnet coil system by:
(a1) initiating a cooling operation of the super-conductive MR magnet coil system;
(a2) initiating an automatic current charging program for the super-conductive MR magnet coil system;
(b1) measuring an actual temperature T_{coil} of the MR magnet coil system and comparing T_{coil} to a predefinable first temperature setpoint value T1ᵣₐₘₚ at which the MR magnet coil system is super-conductive and should be charged;
(b2) if T_{coil}≤T1ᵣₐₘₚ, supplying a charging current to the MR magnet coil system and charging the MR magnet coil system with electric current;
(c) measuring the electric current I_{coil} flowing in the MR magnet coil system (12) and comparing I_{coil} with a predefinable first current setpoint value I1_{target} at which the MR magnet coil system generates a desired magnetic field strength;
(d) repeating steps (b1), (b2) and (c) until I_{coil}=I1_{target}, and
(e) deactivating the current supply to the MR magnet coil system and stopping the automatic current charging program.

2. The method according to claim 1, wherein the following intermediate steps are carried out between step (d) and step (e):
(d1) as soon as I_{coil}=I1_{target}: stopping the cooling operation of the super-conductive MR magnet coil system;
(d2) measuring the actual temperature T_{coil} of the MR magnet coil system and comparing T_{coil} to a predefinable second temperature setpoint value T2ₜₒᵥ, which is lower than a critical transition temperature T_{c} at which the magnet coil system transitions from super-conductive to normal conductive state wherein, at T2ₜₒᵥ, a super-conductive current carrying capacity of the MR magnet coil system is reduced to a predefinable lower value; and
(d3) as soon as T_{coil}=T2ₜₒᵥ: restarting the cooling operation of the super-conductive MR magnet coil system.

3. The method according to claim 2, wherein steps (d1) to (d3) are repeated several times after the criterion T_{coil}=T2ₜₒᵥ has been reached in step (d3).

4. The method according to claim 1, wherein, if T_{coil}>T1ᵣₐₘₚ, in step (b2) the charging of the MR magnet coil system with electric current is interrupted and the cooling operation is continued until T_{coil}≤T1ᵣₐₘₚ; then step (b1) is resumed.

5. The method according to claim 1, wherein a closed cavity is formed around the cooling arm and is sealed fluid-tight with respect to the MR magnet coil system to be cooled and is at least partially filled with liquid helium during normal operation of the MR apparatus, wherein the neck tube is connected via a first valve V1 to a helium gas supply, through which helium gas can be introduced in order to be liquefied on the cooling arm, and wherein the helium in the neck tube is pumped out during step (c), with the following steps:
(c0′) measuring the electric current I_{coil} flowing in the MR magnet coil system and comparing I_{coil} with a predefinable second current setpoint value I2ₚᵤₘₚ<I1_{target} at which the helium in the neck tube (14) should be pumped out; and
(c0″) as soon as I_{coil}≥I2ₚᵤₘₚ, activating a vacuum pump arranged outside the vacuum container, and opening a first shut-off valve in a pumping line leading from the vacuum pump into the neck tube in order to pump helium gas out of the neck tube using the vacuum pump.

6. The method according to claim 5, wherein the pumping line to the neck tube is connected to the vacuum pump via a further valve V3, and wherein the method further comprises a step (f) in which helium is supplied to the neck tube and liquefied.

7. The method according to claim 1 wherein, in step (b1), temperature T_{istshield} on a radiation shield is measured and compared with a predefinable temperature setpoint value T_{shield} and, if T_{istshield}≤T_{shield}, the charging current is supplied according to step (b2).

8. The method according to claim 7, wherein, if T_{istshield}>T_{shield}, charging of the MR magnet coil system with electric current is interrupted in step (b2) and the cooling operation is continued until T_{istshield}≤T_{shield}, after which the method is resumed in step (b1).

9. The method according to claim 1, wherein the predefinable temperature setpoint value T1ᵣₐₘₚ and the predefinable current setpoint value I1_{target} are selected from the following value ranges:
2K<T1ᵣₐₘₚ≤5K,
50 A<I1_{target}≤500 A.

10. The method according to claim 1, wherein the autonomous electrical charging operation of the super-conductive MR magnet coil system is automatically regulated by means of an electronic control unit, wherein the control unit is configured to detect and compare the temperature T_{coil} on the MR magnet coil system with predefined temperature setpoint values, to detect and compare the electric current I_{coil} flowing in the MR magnet coil system with predefined current setpoint values and, if necessary, to actuate valves, a charging mains supply unit, a vacuum pump and functional units of the cold head.

11. The method according to claim 10, wherein the electronic control unit regulates the autonomous electrical charging operation of the super-conductive MR magnet coil system automatically by means of an algorithm taking into account various measured values and parameters and wherein, during the autonomous electrical charging operation of the super-conductive MR magnet coil system, the electronic control unit independently detects critical changes in state and errors in the super-conductive MR magnet coil system and in the cryostat and, in response, uses a predefinable alternative algorithm for further regulation of the autonomous electrical charging operation and/or sends messages, to operating or monitoring personnel.

12. The method according to claim 10, wherein the electronic control unit has access to at least one algorithm for autonomous electrical discharging or partial discharging of the super-conductive MR magnet coil system from an electrically charged state, and wherein the discharging operation is regulated automatically by the electronic control unit with presettable boundary conditions.

13. A magnetic resonance (“MR”) apparatus for carrying out the method according to claim 1, comprising:
a super-conductive MR magnet coil system that is arranged in a vacuum container and is cryogen-free in MR measurement mode;
a vacuum pump and a first shut-off valve arranged in a vacuum line leading from the vacuum pump into the vacuum container;
a cryostat that cools the MR magnet coil system, and that comprises a neck tube which leads through an outer casing of the vacuum container to the MR magnet coil system;
a cooling arm of a cold head arranged at least partially in the neck tube, wherein a closed cavity is formed around the cooling arm, is sealed fluid-tight with respect to the MR magnet coil system to be cooled and is at least partially filled with a cryogenic fluid during normal operation of the MR apparatus;
a temperature sensor for measuring an actual temperature T_{coil} on the MR magnet coil system;
a pressure sensor for measuring an actual pressure Pᵢₛₜ in the vacuum container; and
a control unit is configured to detect and compare the actual temperature T_{coil} on the MR magnet coil system with predefined temperature setpoint values, to detect and compare the actual pressure Pᵢₛₜ in the vacuum container with predefined pressure setpoint values and to actuate the first shut-off valve, the vacuum pump, the cold head and the charging mains supply unit.

14. A control unit for carrying out the method according to claim 1 in an MR apparatus, wherein the control unit is configured to detect and compare an actual temperature T_{coil} of the MR magnet coil system with predefined temperature setpoint values, and to detect and compare an actual pressure Pᵢₛₜ in the vacuum container with predefined pressure setpoint values, the control unit comprising;
a measuring unit to which a temperature sensor for measuring the actual temperature T_{coil} on the MR magnet coil system and a pressure sensor for measuring the actual pressure Pᵢₛₜ in the vacuum container are connected;
an actuating unit for opening and closing a first shut-off valve, for activating and deactivating a vacuum pump and for activating and deactivating a cold head; and
a processor unit which is arranged as an interface between the measuring unit and the actuating unit for comparing the detected sensor parameters with the setpoint parameters and processing the data for actuating the cold head, vacuum pump, shut-off valve and charging mains supply unit.

15. The control unit according to claim 14, wherein a connection from the neck tube to the vacuum pump is provided, wherein the control unit regulates the control of a second shut-off valve to the vacuum pump, wherein a connection from a helium supply to the neck tube is provided, and wherein the control unit regulates control of a supply via a third valve.

16. The method according to claim 2, wherein the predefinable temperature setpoint value T2ₜₒᵥ is selected from the value range 2K≤T2ₜₒᵥ<6K.

17. The method according to claim 5, wherein the predefinable current setpoint value I2ₚᵤₘₚ is selected from the value range 30 A≤I2ₚᵤₘₚ<400 A.

18. The method according to claim 7, wherein the predefinable temperature setpoint value T_{shield} is selected from the value range 30K≤T_{shield}<77K.
